(19) United States
(12) Patent Application Publication
(10) Pub. No.: US 2015/0239774 A1
(43) Pub. Date: Aug. 27, 2015

(54) ANTI-CONDENSATION GLAZING

(71) Applicant: SAINT-GOBAIN GLASS FRANCE, Courbevoie (FR)

(72) Inventors: Driss Lamine, Antony (FR); Sébastien Roy, Le Mesnil Saint Denis (FR)

(21) Appl. No.: 14/382,679

(22) PCT Filed: Mar. 1, 2013
(86) PCT No.: PCT/FR2013/050437

§ 371 Date: Sep. 3, 2014

(30) Foreign Application Priority Data
Mar. 5, 2012 (FR) 1251975

(51) Int. Cl. C03C 17/34; C23C 14/58; C23C 14/10; C23C 14/06; C23C 14/08

(52) U.S. Cl. CPC C03C 17/3435; C23C 14/0652; C23C 14/086; C23C 14/083; C23C 14/10; C23C 14/5806; C23C 14/5813; C23C 14/5826; C03C 2217/948

(57) ABSTRACT

A glazing unit includes a glass substrate equipped on one of its faces, intended to form the face of the glazing unit in the use position, with a thin-film multilayer comprising, from the substrate, a film of a transparent electrically conductive oxide based on indium tin oxide of physical thickness e₁ included in a range extending from 50 to 200 nm, a silicon-nitride barrier film of physical thickness e₂, then a film based on silicon oxide, the thicknesses e₁ and e₂, expressed in nanometers, being such that 0.11≦e₂/e₁≦0.18.

The invention relates to the field of glazing units comprising a glass substrate, equipped on at least one of its faces with a thin-film multilayer.

For environmental reasons and reasons related to the need to save energy, dwellings are currently equipped with multiple glazing units, double glazing units and even triple glazing units, often provided with low-E films, intended to limit heat transfer to the exterior of the dwelling. However, these glazing units, which have a very low thermal transmission coefficient, are prone to water condensing on their external surface, in the form of mist or frost. If the sky is clear overnight, radiative heat exchange with the sky causes a drop in temperature that is not sufficiently compensated for by heat coming from the interior of the dwelling. When the temperature of the external surface of the glazing unit drops below the dew point, water condenses on said surface, reducing visibility through the glazing unit in the morning, sometimes for a number of hours.

In order to solve this problem, it is known to place a low-E film on face 1 of the glazing unit (the external face), for example a film of a transparent electrically conductive oxide (TCO), so as to reduce radiative exchange with the sky. Patent application WO 2007/115796 for example provides for the use of a multilayer comprising a TCO film (typically a fluorine-doped tin oxide), a blocking film and finally a photocatalytic film.

Patent application FR 2 963 343 also describes a multilayer comprising a TCO film, especially one made of ITO (indium tin oxide), an intermediate low-refractive-index film, typically made of silica, and lastly a photocatalytic film, the thickness of the intermediate film being optimized in order to decrease as little as possible the G-value of the glazing unit.

If ITO is to be used a heat treatment, typically a tempering heat treatment, is required in order to decrease as much as possible both the electrical resistivity and the light absorption of the ITO. It has been observed by the inventors that in this type of multilayer optimal ITO performance can be obtained only by precisely controlling the oxidation state of the ITO.

The aim of the invention is to optimize the optical and anti-condensation performance of glazing units equipped with an ITO-based coating capable of limiting, even preventing, condensation (mist or frost) from appearing on the external face.

For this purpose, the invention relates to a glazing unit comprising a glass substrate (1) equipped on one of its faces, intended to form face 1 of said glazing unit in the use position, with a thin-film multilayer comprising, from said substrate (1), a film (2) of a transparent electrically conductive oxide based on indium tin oxide of physical thickness e₁ comprised in a range extending from 50 to 200 nm, a silicon-nitride barrier film (3) of physical thickness e₂, then a film (4) based on silicon oxide, said thicknesses e₁ and e₂, expressed in nanometers, being such that 0.11≦e₂/e₁≦0.18.

The expression “face 1” of the glazing unit is understood to mean, as is common in the art, the external face of the glazing unit, which face is intended to be positioned in contact with the exterior of the dwelling. The faces of a glazing unit are numbered starting from the exterior, thus face 2 is the face opposite face 1, in other words the other face of the same glass pane. In a multiple glazing unit, comprising two or more glass panes, face 3 is the face of the second glass pane of the glazing unit that faces face 2 and face 4 is the face opposite face 3, etc.

The glazing unit according to the invention is preferably a multiple glazing unit, especially a double or triple glazing unit, or a higher-multiple glazing unit, for example a quadruple glazing unit. This is because these glazing units have a low thermal transmission coefficient, and are affected more by condensation effects. A double glazing unit is generally formed by two glass panes that face each other and house a gas-filled cavity, for example filled with air, argon or xenon or indeed krypton. Generally, a spacer bar in the form of a metal strip, for example an aluminum strip, is placed on the periphery of the glazing unit, between the glass panes, and securely fastened to the glass panes by an adhesive. The periphery of the glazing unit is sealed using a mastic, for example a silicone, polysulfide or polyurethane mastic, in order to prevent any moisture from entering the gas-filled cavity. In order to limit the ingress of moisture a molecular sieve is often placed in the spacer bar. A triple glazing unit is formed in the same way, though the glass panes are then three in number.

When the glazing unit according to the invention is a triple glazing unit, at least one other face, chosen from faces 2 to 5, is preferably coated with a low-B multilayer. This may in particular be a thin-film multilayer comprising at least one silver film, the or each silver film being placed between dielectric films. The term “low-E” is understood to mean providing-an emissivity generally of at most 0.1, especially 0.05. Preferably, two other faces, especially faces 2 and 5 or faces 3 and 5, are coated with such a multilayer. Other configurations are also possible, but less preferable: faces 2 and 3, 2 and 4, 3 and 4, 4 and 5, faces 2, 3 and 4, faces 2, 3 and 5, faces 2, 4 and 5 or faces 2, 3, 4 and 5. Other types of multilayer may be placed on the faces of the glazing unit, for example antireflective multilayers, on face 2, 3, 4, 5 or 6.

When the glazing unit according to the invention is a double glazing unit, face 2 is advantageously coated with a low-E multilayer, especially of the type described above. Alternatively, face 2 may be coated with a solar-control multilayer (in particular based on niobium or niobium nitride), though this is not preferred because such a multilayer reduces the G-value.

The glazing unit according to the invention may be employed as any type of glazing unit. It may be incorporated into curtain walling, a roof or a veranda. It may be positioned vertically or at an inclination.

The glass substrate is preferably transparent and colorless (it is then a question of clear or extra-clear glass). Clear glass typically contains an iron oxide weight content of about 0.05 to 0.2%, whereas an extra-clear glass generally contains about 0.005 to 0.03% iron oxide. The glass may also be tinted, for example blue, green, gray or bronze, though this embodiment, which reduces the G-value, is not preferred. The glass is usually mineral glass, preferably a soda-lime-silica glass, but it may also be a borosilicate or aluminoborosilicate glass. The thickness of the substrate is generally comprised in a range extending from 0.5 mm to 19 mm, preferably from 0.7 to 9 mm, especially from 2 to 8 mm and even from 4 to 6 mm. The same applies, if required, to the other glass panes of the multiple glazing unit.

The glass substrate is preferably float glass, i.e. likely to have been obtained via a process that consists in pouring molten glass onto a bath of molten tin (the float bath). In this case, the multilayer may equally well be placed on the “tin” side as on the “atmosphere” side of the substrate. The expressions “atmosphere side” and “tin side” are respectively understood to mean the face of the substrate that made contact with the atmosphere above the float bath and the face of the substrate that made. contact with the molten tin. The tin side contains a small amount of tin on its surface, the tin having diffused into the structure of the glass.

At least one glass pane of the glazing unit according to the invention may be thermally tempered or toughened, so as to increase its strength. Preferably, the substrate equipped with the multilayer according to the invention is thermally tempered. As described below, thermal tempering may also be used to improve the emissivity properties of the ITO film. Preferably, the electrical resistivity of the multilayer after the temper has been carried out is at most 2.2×10⁻⁴ Ω·cm, especially at most 2.1×10⁻⁴ Ω·cm and even 2.0×10⁻⁴ Ωcm. The emissivity and electrical resistivity properties are closely related.

To improve the acoustic or anti-break-in properties of the glazing unit according to the invention, at least one glass pane of the glazing unit is possibly laminated to another pane by means of an intermediate sheet made of a polymer such as polyvinyl butyral (PVB) or polyurethane (PU).

The ITO-based film preferably consists of ITO. The atomic percentage of Sn is preferably comprised in a range extending from 5 to 70%, especially from 6 to 60% and advantageously from 8 to 12%.

These films have a good weatherability, necessary when the multilayer is placed on face 1 of the glazing unit, which is not the case for other low-E films such as silver films. The latter must necessarily be located on an internal face of the multiple glazing unit.

ITO is also particularly appreciated for its high electrical conductivity, permitting small thicknesses to be used to obtain a given emissivity level, thereby minimizing the reduction in G-value. Easily deposited by cathode sputtering, especially magnetron sputtering, these films are noteworthy for their low roughness meaning that they are less prone to fouling. Specifically, during manufacture, handling and maintenance of the glazing units, rougher films have a tendency to trap various residues that are particularly difficult to remove.

The physical thickness e₁ of the TCO film is adjusted so as to obtain the desired emissivity and therefore the anti-condensation performance sought. The emissivity of the TCO film is preferably lower than or equal to 0.4 and especially 0.3. The physical thickness e₁ of the ITO-based film will generally be at least 60 nm, especially 70 nm, and often 180 nm at most.

For a given anti-condensation performance, the required emissivity depends on various factors including the inclination of the glazing unit and its thermal transmission coefficient Ug. Typically, a glazing unit that is inclined and/or has a low thermal transmission coefficient will require a lower emissivity and therefore a larger thickness e₁ will be used.

When the glazing unit is intended to be placed vertically, the emissivity is preferably at most 0.4 and even 0.3. The physical thickness e₁ will then generally be at least 60 nm and often 120 nm at most.

When the glazing unit is intended to be inclined, for example in roofing applications, or when the thermal transmission coefficient Ug is smaller than or equal to 1 W/(m²·K), even 0.6 W/(m²·K), the emissivity is preferably at most 0.3, or 0.2 or even 0.18. The physical thickness e₁ will preferably be at least 60 nm, even 70 or 100 nm and 200 nm at most.

The term “emissivity” is understood to mean the emissivity at 283 K normal to the unit, as defined in standard EN 12898. As demonstrated in the rest of the text, the choice of the thickness of the barrier film allows, for a given thickness of ITO, its resistivity and therefore its emissivity to be optimized.

In order to minimize the G-value of the glazing unit, the refractive index of the transparent electrically conductive oxide film is preferably comprised in a range extending from 1.7 to 2.5 and/or the refractive index of the film based on silicon oxide is preferably comprised in a range extending from 1.40 to 1.55 and especially from 1.40 to 1.50. Throughout the text, refractive indices are measured, for example with an ellipsometer, at a wavelength of 550 nm.

The film based on silicon oxide is advantageously a silica film. It will be understood that the silica may be doped, or nonstoichiometric. By way of example, the silica may be doped with aluminum or boron atoms, so as to make it easier to sputter. In the case of chemical vapor deposition (CVD), the silica may be doped with phosphorus or boron atoms, thereby accelerating deposition. The silica may also be doped with nitrogen or carbon atoms in sufficiently small amounts that the refractive index of the film remains in the aforementioned ranges. The film based on silicon oxide has the advantage of protecting the TCO film, endowing it with better weatherability and an improved tempering withstand.

The physical thickness of the film based on silicon oxide is preferably comprised in a range extending from 20 to 100 nm, especially from 30 nm to 90 nm and even from 40 to 80 nm.

The silicon-nitride barrier film, placed between the ITO-based film and the film based on silicon oxide, makes it possible to control with a high precision the oxidation state of the ITO, and therefore its electrical and optical properties following heat treatment, especially tempering heat treatment. The silicon nitride may be nitrogen stoichiometric, nitrogen substoichiometric or even nitrogen superstoichiometric. A judicious choice of the thickness of the barrier film, depending on the thickness of the ITO film, allows the properties of the latter to be optimized. Preferably, the ratio e₂/e₁ is at least 0.12 even 0.13 and/or at most 0.17, especially 0.16, even 0.15 or 0.14. It is advantageously comprised in a range extending from 0.12 to 0.15.

Preferably, the silicon-nitride barrier film is deposited on and in contact with the ITO-based film. For its part, the film based on silicon oxide is preferably deposited on and in contact with the silicon-nitride barrier film.

The film based on silicon oxide may be the last film of the multilayer and therefore the film making contact with the atmosphere. Alternatively, at least one other thin film may be deposited on top of the film based on silicon oxide.

Thus, a photocatalytic film based on titanium oxide, the physical thickness of which is advantageously at most 30 nm, especially 20 nm, or 10 nm or even 8 nm, may be placed on top of, preferably on and in contact with, the film based on silicon oxide.

Very thin photocatalytic films, although less active photocatalytically speaking, have however good self-cleaning, antifouling and antimisting properties. Even for films with a very small thickness, the photocatalytic titanium oxide has the particularity of becoming extremely hydrophilic when it is irradiated with solar light, with water contact angles smaller than 5° and even 1°, thereby allowing .water to run off more easily, removing dirt deposited on the surface of the film. Furthermore, thicker films reflect more light, which has the effect of reducing G-value.

The photocatalytic film is preferably a film of titanium oxide in particular having refractive index comprised in the range extending from 2.0 to 2.5. The titanium oxide is preferably at least partially crystallized in the anatase form, which is the most active phase from the point of view of photocatalysis. Mixtures of the anatase phase and the rutile phase have also been observed to be very active. The titanium dioxide may optionally be doped with a metal ion, for example a transition-metal ion, or with atoms of nitrogen, carbon or fluorine, etc. The titanium dioxide may also be substoichiometric or superstoichiometric.

In this embodiment, all of the surface of the photocatalytic film, especially a titanium-oxide-based film, preferably makes contact with the exterior, so as to be able to exercise its self-cleaning function unchecked. It may however be advantageous to coat the photocatalytic film, especially a film of titanium dioxide, with a thin hydrophilic film, especially based on silica, so as to improve the durability of the hydrophilicity.

In order to optimize the G-value of the glazing unit according to the invention, the optical thicknesses at 550 nm of the photocatalytic film (e₃) and of the film based on silicon oxide (e₄), expressed in nanometers, are preferably such that 100·e^{-0.025e}^{₃}≦e₄≦135·e^{-0.018e}^{₃}, the optical thickness e₃ being at most 50 nm and the refractive index (again at 550 nm) of the film based on silicon oxide being comprised in a range extending from 1.40 to 1.55.

It is also possible to place a neutralizing film, or a neutralizing film multilayer, between the substrate and the film of a transparent electrically conductive oxide. In the case of a single film, its refractive index is preferably comprised between the refractive index of the substrate and the refractive index of said film of a transparent electrically conductive oxide. Such films or film multilayers make it possible to influence the appearance of the glazing unit in reflection, especially its color in reflection. Bluish colors, characterized by negative b* color coordinates, are preferred. By way of nonlimiting example, it is possible to use a film of mixed silicon tin oxide (SiSnOₓ), of silicon oxycarbide or oxynitride, of aluminum oxide or of mixed titanium silicon oxide. A film multilayer comprising two films of high and low index, for example a TiOₓ/SiOₓ, SiNₓ/SiOₓ or ITO/SiOₓ multilayer may also be used. The physical thickness of this or these films is preferably comprised in a range extending from 5 to 70 nm and especially from 15 to 30 nm. The preferred neutralizing films or multilayers are a neutralizing film made of a silicon oxynitride or an SiNₓ/SiOₓ multilayer.

An adhesion film is preferably placed between the substrate and the neutralizing film or multilayer. This film, which advantageously has a refractive index near that of the glass substrate, allows tempering resistance to be improved by promoting adhesion of the neutralizing film. The adhesion film is preferably made of silica. Its physical thickness is preferably comprised in a range extending from 20 to 200 nm and especially from 30 to 150 nm.

The various preferred embodiments described above may of course be combined with one another. All possible combinations are not explicitly described in the present text in order not to clutter it unduly. A few examples of particularly preferred multilayers are given below:

1. Glass/(SiOₓ)/SiOₓN_{y}/ITO/SiNₓ/SiOₓ/(TiOₓ)

2. Glass/SiOₓ/SiNₓ/SiOₓ/ITO/SiNₓ/SiOₓ/(TiOₓ)

3. Glass/SiNₓ/SiOₓ/ITO/SiNₓ/SiOₓ/(TiOₓ)

In these multilayers, the physical thickness of the (optional) TiO₂ film is advantageously at most 15 nm and even 10 nm. The physical thickness e₁ of the TCO film is chosen independently depending on the desired emissivity as explained above in the present description. The physical thickness e₂ of the silicon-nitride barrier film then depends on the thickness e₁, and it is chosen to optimize the optical, resistivity and emissivity properties of the ITO.

Multilayers 1 to 3 are preferably obtained by magnetron cathode sputtering. Examples 1 and 2 contain, on the glass, an (optional for example 1) adhesion film made of silica, then a neutralizing film made of silicon oxynitride or a neutralizing multilayer consisting of a film of silicon nitride surmounted by a film of silicon oxide, the TCO film (made of ITO or based on ITO), a silicon-nitride barrier film, a film made of silicon oxide and lastly the (optional) photocatalytic film made of titanium oxide. Example 3 corresponds to example 2, but without the silica adhesion film. The formulae given are not intended to be understood as specifying the actual stoichiometry of the films and are not intended to preclude optional doping. In particular, the silicon nitride and/or silicon oxide may be doped, for example with aluminum. The oxides and nitrides may not be stoichiometric (though they may be), this being indicated in the formulae by the use of the index “x”, which of course need not necessarily be the same for all the films.

The glazing unit according to the invention is preferably obtained by a method comprising a plurality of steps. The multilayer films are deposited on the glass substrate, which generally takes the form of a large glass pane measuring 3.2×6 m², or directly on the ribbon of glass during or just after the float process, and then the substrate is cut to the final size of the glazing unit. After the edges have been finished the multiple glazing unit is then manufactured by associating the substrate with other glass panes, themselves optionally equipped beforehand with functional coatings, for example low-E coatings.

The various films of the multilayer may be deposited on the glass substrate by any thin-film deposition process. It may for example be a question of a sol-gel process, (liquid or solid) pyrolysis, chemical vapor deposition (CVD), especially plasma-enhanced chemical vapor deposition (PECVD), optionally at atmospheric pressure (AP-PECVD), or evaporation.

Preferably, the films of the multilayer are obtained by cathode sputtering, especially magnetron cathode sputtering. In this process, a plasma is created under a high vacuum near a target comprising the chemical elements to be deposited. The active species of the plasma bombard the target and tear off said elements, which are deposited on the substrate forming the desired thin film. This process is said to be “reactive” when the film consists of a material resulting from a chemical reaction between the elements torn from the target and the gas contained in the plasma. The main advantage of this process is that it is possible to deposit a very complicated film multilayer on a given line by running the substrate under various targets in succession, this generally taking place in one and the same device.

However, the magnetron process has a drawback when the substrate is not heated during the deposition: the ITO (and optionally titanium oxide) films thus obtained are poorly crystallized such that their respective emissivity and photocatalytic activity properties are not optimized. A heat treatment is thus required.

This heat treatment, intended to improve the crystallization of the film of a transparent electrically conductive oxide based on indium tin oxide (and optionally the photocatalytic film), is preferably chosen from tempering, annealing or rapid annealing treatments. The. improvement in the crystallization may be quantified by an increase in the degree of crystallization (i.e. the proportion of crystalline material by weight or by volume) and/or the size of the crystalline grains (or the size of the coherent diffraction domains measured by X-ray diffraction methods or by Raman spectroscopy). This improvement in crystallization may also be verified indirectly, by measuring the improvement in the properties of the film. In the case of a TCO film, emissivity decreases, preferably by at least 5% in relative magnitude, even at least 10% or 15%, and likewise for its light and energy absorption. In the case of titanium dioxide films, the improvement in crystallization leads to an increase in photocatalytic activity. This activity is generally measured by following the degradation of model pollutants, such as stearic acid or methylene blue.

The tempering or annealing treatment is generally carried out in a furnace, a tempering furnace or an annealing furnace, respectively. The entire substrate is raised to a high temperature, to at least 300° C. in the case of an anneal, and to at least 500° C., even 600° C., in the case of a temper.

The rapid annealing is preferably implemented using a flame, a plasma torch or laser radiation. In this type of process a relative motion is created between the substrate and the device (flame, laser, plasma torch). Generally, the device is stationary, and the coated substrate runs past the device so that its surface may be treated. These processes allow a high energy density to be delivered to the coating to be treated in a very short space of time, thus limiting diffusion of the heat toward the substrate and therefore heating of said substrate. The temperature of the substrate is generally at most 100° C. or 50° C. and even 30° C. during the treatment. Each point of the thin film is subjected to the rapid-annealing treatment for an amount of time generally smaller than or equal to 1 second and even 0.5 seconds.

The rapid-annealing heat treatment is preferably implemented using laser radiation emitted in the infrared or visible. The wavelength of the laser radiation is preferably comprised in a range extending from 530 to 1200 nm, or from 600 to 1000 nm, especially from 700 to 1000 nm and even from 800 to 1000 nm. Preferably laser diodes are used, for example emitting at a wavelength of about 808 nm, 880 nm, 915 nm or even 940 nm or 980 nm. Systems of diodes make it possible to obtain very high powers, allowing powers per unit area at the coating to be treated of higher than 20 kW/cm² and even 30 kW/cm² to be obtained.

The laser radiation preferably issues from at least one laser beam forming a line (called a “laser line” in the rest of the text) that simultaneously irradiates all or some of the width of the substrate. This embodiment is preferred because it avoids the use of expensive displacement systems, which are generally bulky and difficult to maintain. The in-line laser beam may especially be obtained using systems of high-power laser diodes combined with focusing optics. The thickness of the line is preferably comprised between 0.01 and 1 mm. The length of the line is typically comprised between 5 mm and 1 m. The profile of the line may especially be a Gaussian or tophat profile. The laser line simultaneously irradiating all or some of the width of the substrate may consist of a single line (then irradiating the entire width of the substrate), or of a plurality of optionally separate lines. When a plurality of lines is used, it is preferable for them to be arranged so that all of the area of the multilayer is treated. The or each line is preferably placed at right angles to the run direction of the substrate, or placed obliquely. The various lines may treat the substrate simultaneously, or at different times. What is important is for all of the area to be treated to be treated. The substrate may thus be made to move, especially so as to run translationally past the stationary laser line, generally below but optionally above the laser line. This embodiment is particularly advantageous for a continuous treatment. Alternatively, the substrate may be stationary and the laser may be moved. Preferably, the difference between the respective speeds of the substrate and the laser is greater than or equal to 1 meter per minute, or 4 meters per minute or even 6, 8, 10 or 15 meters per minute, so as to ensure a high treatment rate. When it is the substrate that is made to move, especially translationally, it may be moved using any mechanical conveying means, for example belts, rollers or trays running translationally. The conveying system is used to control and regulate the run speed. The laser may also be moved so as to adjust its distance from the substrate, which may in particular be useful when the substrate is curved, but not only in such a case. Indeed, it is preferable for the laser beam to be focused onto the coating to be treated so that the latter is located at a distance of less than or equal to 1 mm from the focal plane. If the system for moving the substrate or moving the laser is not sufficiently precise as regards the distance between the substrate and the focal plane, it is preferable to be able to adjust the distance between the laser and the substrate. This adjustment may be automatic and in particular regulated using a distance measurement upstream of the treatment.

The laser radiation device may be integrated into a film deposition line, for example a magnetron sputtering line, or a chemical vapor deposition (CVD) line, especially a plasma-enhanced chemical vapor deposition (PECVD) line, whether under vacuum or at atmospheric pressure (AP-PECVD).

Another subject of the invention is the use of the glazing unit according to the invention to reduce the appearance of water condensation (especially mist or frost) on the surface of said glazing unit.

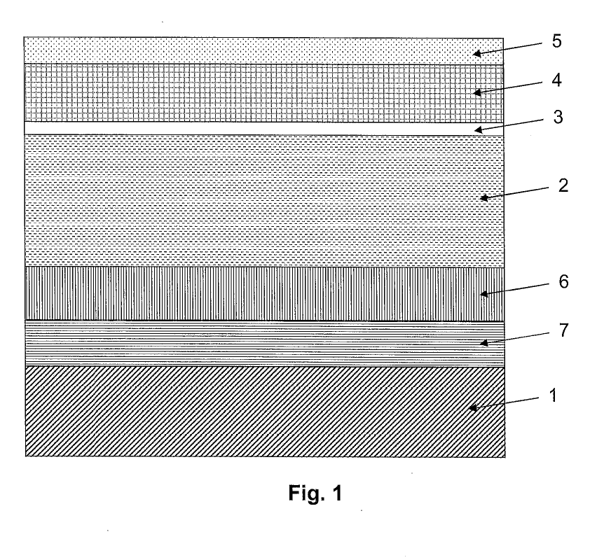

FIG. 1 schematically illustrates a cross section through part of the glazing unit according to the invention. Only the multilayer placed on face 1 of the glazing unit and a portion of the glass substrate are shown.

Shown, deposited on the (typically glass) substrate 1 are: the film 2 of a transparent electrically conductive oxide film (typically made of ITO), the barrier film 3 based on silicon nitride and the film 4 based on silicon oxide (typically SiOₓ). The photocatalytic film 5 (typically made of TiOₓ), the neutralizing film or multilayer 6 (typically an SiNₓ/SiOₓ multilayer) and the adhesion film 7 (for example made of SiOₓ) are optional films.

The following examples illustrate the invention without however limiting it.

### EXAMPLE 1

Starting from the substrate, multilayers made up of a neutralizing multilayer consisting of a silicon-nitride film of about 20 nm in thickness then a silica film of about 20 to 30 nm in thickness, then an ITO film, a silicon-nitride barrier film, a silicon-oxide film of about 50 to 60 nm in thickness, and lastly a photocatalytic film made of titanium dioxide of about 7 to 10 nm in thickness were deposited by magnetron cathode sputtering on a 4 mm-thick clear glass substrate. All of these thicknesses are physical thicknesses.

The silicon-oxide and silicon-nitride films were deposited using targets of aluminum-doped (2 to 8 at %) silicon.

The thickness e₁ of the ITO film was 120 nm.

The thickness e₂ of the silicon-nitride barrier film varied depending on the trial from 12 to 24 nm.

The glass sheets thus obtained were then thermally tempered in a conventional way by heating the glass to about 700° C. for a few minutes before rapidly cooling it using jets of air.

Table 1 below collates for the various trials:
the ratio e₂/e₁;
the sheet resistance of the multilayer, denoted R_{c} and expressed in ohms, before and after tempering, measured in a conventional way using a contactless measuring device sold by Nagy Messsysteme GmbH;
the electrical resistivity of the multilayer, denoted ρ and expressed in ohms·cm before and after tempering, calculated from the measurement of sheet resistance and of the thickness e₁ (determined by scanning electron microscope); and
the light absorption of the substrate coated with its multilayer, measured from optical transmission and reflection spectra and denoted A.

TABLE 1

| | | C1 | 1 | 2 | C2 |
|---|---|---|---|---|---|
| e₂ (nm) | | 12 | 15 | 16 | 24 |
| e₂/e₁ | | 0.10 | 0.125 | 0.133 | 0.20 |
| R_{c} (Ω) | before | 110 | 120 | 110 | 110 |
| | after | 29.4 | 15.0 | 15.2 | 19.1 |
| ρ | before | 13.0 | 14.4 | 13.0 | 13.0 |
| (10⁻⁴ Ω · cm) | after | 3.5 | 1.8 | 1.8 | 2.3 |
| A (%) | before | 20 | 22 | 20 | 20 |
| | after | 1.9 | 4.0 | 4.2 | 6.3 |

### EXAMPLE 2

In this second series of examples, the physical thickness e₁ of the ITO film was 75 nm. The thickness e₂ varied from 9 to 24 nm depending on the trial.

Table 2 below collates the results obtained.

TABLE 2

| | | 3 | C3 | C4 |
|---|---|---|---|---|
| e₂ (nm) | | 9 | 16 | 24 |
| e₂/e₁ | | 0.12 | 0.21 | 0.31 |
| R_{c} (Ω) | before | 250 | 250 | 250 |
| | after | 26.0 | 30.6 | 39.3 |
| ρ | before | 19 | 19 | 19 |
| (10⁻⁴ Ω · cm) | after | 1.95 | 2.33 | 2.93 |
| A (%) | before | 15 | 15 | 15 |
| | after | 3.2 | 4.4 | 5.2 |

Examples C1 to C4 are comparative examples, not satisfying the condition on the ratio e₂/e₁. Examples 1 to illustrate the advantages of the invention, and particularly the importance of the choice of the ratio e₂/e₁. This ratio does not influence the optical and resistivity (and therefore emissivity) properties of the multilayer post-deposition. In contrast, these properties, measured after heat treatment (here a temper) are greatly influenced by the choice of this ratio. When the latter is comprised in the range according to the invention, the resistivity (and therefore the emissivity) of the multilayer is optimal after the temper, reaching a value of 1.9×10⁻⁴ Ω·cm or less. In contrast, if the thickness of the barrier film is too large or too small the resistivity and emissivity properties of the glazing unit, and therefore its anti-condensation properties, are observed to degrade. Too small a thickness e₂ leads to a large increase in resistivity, whereas too large a thickness is accompanied both by a high resistivity and a high light absorption.

Glazing units according to the invention allow the appearance of water condensation such as mist or frost to be greatly reduced.

1. A glazing unit comprising a glass substrate equipped on one of its faces, intended to form a face of said glazing unit in the use position, with a thin-film multilayer comprising, from said substrate, a film of a transparent electrically conductive oxide based on indium tin oxide of physical thickness e₁ comprised in a range extending from 50 to 200 nm, a silicon-nitride barrier film of physical thickness e₂, then a film based on silicon oxide, said thicknesses e₁ and e₂, expressed in nanometers, being such that 0.11≦e₂/e₁≦0.18.

2. The glazing unit as claimed in claim 1, said glazing unit being a multiple glazing unit.

3. The glazing unit as claimed in claim 1, wherein the glass substrate is thermally tempered.

4. The glazing unit as claimed in claim 1, wherein an emissivity of the film of a transparent electrically conductive oxide is lower than or equal to 0.4.

5. The glazing unit as claimed in claim 1, wherein the ratio e₂/e₁ is comprised in a range extending from 0.12 to 0.15.

6. The glazing unit as claimed in claim 1, wherein the physical thickness of the film based on silicon oxide is comprised in a range extending from 20 to 100 nm.

7. The glazing unit as claimed in claim 1, wherein a photocatalytic film based on titanium oxide, the physical thickness of which is at most 30 nm, is placed on top of the film based on silicon oxide.

8. The glazing unit as claimed in claim 1, wherein a neutralizing film or film multilayer is placed between the substrate and the film of a transparent electrically conductive oxide.

9. The glazing unit as claimed in claim 8, wherein an adhesion film is placed between the substrate and the neutralizing film or multilayer.

10. The glazing unit as claimed in claim 1, wherein the multilayer positioned on said face is chosen from the following multilayers:
Glass/SiOₓ/SiOₓN_{y}/ITO/SiNₓ/SiOₓ/TiOₓ
Glass/SiOₓ/SiNₓ/SiOₓ/ITO/SiNₓ/SiOₓ/TiOₓ
Glass/SiNₓ/SiOₓ/ITO/SiNₓ/SiOₓ/TiOₓ

11. The glazing unit as claimed in claim 1, said glazing unit being a triple glazing unit in which at least one other face is coated with a low-E multilayer.

12. A process for obtaining a glazing unit as claimed in claim 1, comprising depositing the films by cathode sputtering, subjecting the films to a heat treatment intended to improve the crystallization of the film of a transparent electrically conductive oxide, said heat treatment being chosen from tempering, annealing and rapid annealing treatments.

13. The process as claimed in claim 12, wherein the rapid anneal is implemented using a flame, a plasma torch or laser radiation.

14. A method comprising using the glazing unit as claimed in claim 1 to reduce an appearance of water condensation on the surface of said glazing unit.

15. The glazing unit as claimed in claim 2, said glazing unit being a double glazing unit.

16. The glazing unit as claimed in claim 2, said glazing unit being a triple glazing unit,

17. The glazing unit as claimed in claim 4, wherein the emissivity of the film of a transparent electrically conductive oxide is lower than or equal to 0.3.

18. The glazing unit as claimed in claim 6, wherein the physical thickness of the film based on silicon oxide is comprised in a range extending from 30 to 90 nm.

19. The glazing unit as claimed in claim 7, wherein the physical thickness of the photocatalytic film is at most 20 nm.
